(19) United States
(12) Patent Application Publication
(10) Pub. No.: US 2010/0163820 A1
(43) Pub. Date: Jul. 1, 2010

(54) PHASE CHANGE MEMORY DEVICE HAVING A REDUCED CONTACT AREA AND METHOD FOR MANUFACTURING THE SAME

(76) Inventor: Min Seok Son, Gyeonggi-do (KR)

Correspondence Address: LADAS & PARRY LLP, 224 SOUTH MICHIGAN AVENUE, SUITE 1600, CHICAGO, IL, 60604, US

(21) Appl. No.: 12/493,562

(22) Filed: Jun. 29, 2009

(30) Foreign Application Priority Data
Dec. 26, 2008 (KR) 10-2008-0134269

(51) Int. Cl. H01L 47/00; H01L 21/00

(52) U.S. Cl. 257/2; 438/482; 257/E21.001; 257/E47.001

(57) ABSTRACT

A phase change memory device having a reduced contact area and a method for manufacturing the same is presented. The phase change random access memory device includes a bottom electrode contact pattern layer, and at least one phase change pattern layer formed on a sidewall of the bottom electrode contact pattern layer. The contact areas are minimized by being between the narrow width of the bottom electrode contact pattern layer, i.e., at the sidewall, and the phase change pattern layers. As a result the minimized contact area is proportional to the thickness of the bottom electrode contact pattern layer.

### CROSS-REFERENCES TO RELATED APPLICATION

The present application claims priority under 35 U.S.C. 119(a) to Korean application number 10-2008-0134269, filed on Dec. 26 2008, in the Korean Patent Office, which is incorporated by reference in its entirety as if set forth in full.

### BACKGROUND OF THE INVENTION

1. Technical Field

The embodiments described herein relate to a phase change memory device and a method for manufacturing the same and, more particularly, to a phase change memory device having a reduced contact area between the phase change layer and a bottom electrode contact and a method for manufacturing the same.

2. Related Art

With the rapid development of intellectual technologies, next generation memory devices having high-speed and mass storage characteristics are needed in the use of portable information telecommunication apparatuses and systems which process massive amounts of information by wireless communication schemes. Next generation memory devices generally exhibit nonvolatile capabilities as those in flash memory devices, high-speed operating characteristics as those of SRAM (Static Random Access Memory), and the highly integrated memory characteristics as those of DRAM (Dynamic RAM) and further exhibit low power consumption characteristics. Since FRAM (Ferroelectric RAM), MRAM (Magnetic RAM), PRAM (Phase-change RAM) and NFGM (Nano Floating Gate Memory) exhibit excellent data retention characteristics and superior read and write capabilities as compared to the conventional memory devices. However, continued research and development has been focused on realizing optimum capabilities of these memory devices. Research on the PRAMs have been actively conducted partially because of their simple structure, their potential low cost and their promising high speed operations.

PRAMs have a phase change layer. A presently preferred composition of a phase change layer is that made from various chalcogenide glasses. These chalcogenide glasses can be easily and reversibly “switched” between two states with the application of heat between an ordered crystalline solid state and a disordered amorphous solid state. Some of the preferred chalcogenide glasses are composed of various mixtures containing Ge, Sb, and Te (GST) are already found in existing phase change layer in contemporaneous PRAMs. The reversible phase change between the ordered crystalline and the disordered amorphous solid states can be directed by carefully controlling the amount and flux of heat through this layer. For GST phase change materials this reversible phase change as a function of heat can be achieved as a function of applied current and annealing time. In these types of GST phase change layers, the amorphous disordered solid state usually exhibits a higher resistance than that of the ordered crystalline solid state. Because of this change in resistance corresponding to the particular solid state, one can design a data storage scheme exploiting this physical property change to construct a semiconductor memory device.

One preferred design for changing the phase change is to apply heat from a bottom electrode contact in which the bottom electrode contact is positioned below the phase change layer. When current from a lower switching element is applied onto the bottom electrode contact then electrical resistive heating (i.e., Joule heat) consequentially occurs at the interface of the bottom electrode contact and the phase change layer. Accordingly, it is preferable that the bottom electrode contact is made up of a material having a high sheet resistance and it is also preferred that the contact area (i.e., the interface) between the bottom electrode contact and that of the phase change layer is minimized.

Unfortunately, with the ever continuous trend of increasingly concentrating the integration of the semiconductor memory devices, the critical dimensions needed to be achieved to form highly resolved patterns and holes are soon thought to be beyond the physical capabilities of their respective fabrication techniques such as photolithography. Accordingly it is very difficult to form ultra high resolution structures such as ultra fine bottom electrode contacts that can provide the desired reset currents.

### SUMMARY

A phase change memory device capable of reducing a contact area of a bottom electrode contact of a phase change layer and a method for manufacturing the same is described herein.

According to one aspect, a phase change random access memory device comprises a bottom electrode contact pattern layer, and phase change pattern layers formed on sidewalls of the bottom electrode contact pattern layer, whereby contact areas between the bottom electrode contact pattern layer and the phase change pattern layers are determined based on a thickness of the bottom electrode contact pattern layer.

According to another aspect, a method for forming a phase change random access memory device, the method comprises providing a semiconductor substrate having a switching element, forming a bottom electrode contact pattern layer on the semiconductor substrate and then forming a first resulting structure, wherein the bottom electrode contact pattern layer is electrically coupled to the switching element, and forming phase change pattern layers which are in contact with sidewalls of the bottom electrode contact pattern layer and then forming a second resulting structure, whereby contact areas between the bottom electrode contact pattern layer and the phase change pattern layers are determined based on a thickness of the bottom electrode contact pattern layer.

According to further another aspect, a phase change random access memory device comprises a semiconductor substrate in which a PN diode is formed, a bottom electrode contact pattern layer electrically coupled to the PN diode, wherein the bottom electrode contact pattern layer has a wider width than the PN diode, phase change pattern layers formed on sidewalls of the bottom electrode contact pattern layer, an interlayer insulating layer buried between the phase change pattern layers, and upper electrodes formed on the phase change pattern layers such that the upper electrodes are electrically coupled to the phase change pattern layers, whereby contact areas between the bottom electrode contact pattern layer and the phase change pattern layers are determined based on a thickness of the bottom electrode contact pattern layer.

According to still another aspect, a method for forming a phase change random access memory device, the method comprises providing a semiconductor substrate having a switching element, forming a bottom electrode contact pattern layer on the semiconductor substrate and then forming a first resulting structure, wherein the bottom electrode contact pattern layer is electrically coupled to the switching element, forming phase change pattern layers which are in contact with sidewalls of the bottom electrode contact pattern layer and then forming a second resulting structure, burying an interlayer insulating layer, which is planarized, between the phase change pattern layers, and forming upper electrodes on the phase change pattern layers such that the upper electrodes are electrically coupled to the phase change pattern layers, whereby contact areas between the bottom electrode contact pattern layer and the phase change pattern layers are determined based on a thickness of the bottom electrode contact pattern layer.

These and other features, aspects, and embodiments are described below in the section entitled “Detailed Description.”

### BRIEF DESCRIPTION OF THE DRAWINGS

The above and other aspects, features and other advantages of the subject matter of the present disclosure will be more clearly understood from the following detailed description taken in conjunction with the accompanying drawings, in which:

FIGS. 1 to 4 are cross-sectional views illustrating an example of a method for manufacturing a phase change memory device according to one embodiment;

FIG. 5 is a cross-sectional view illustrating an example of an example of a phase change memory device according to another embodiment;

FIG. 6 is an equivalent circuit of the phase change memory device according to one embodiment;

FIGS. 7 to 9 are cross-sectional views illustrating an example of a method for manufacturing a phase change memory device according to another embodiment;

FIG. 10 is a top view illustrating an upper electrode and a phase change pattern in the phase change memory device according to another embodiment; and

FIGS. 11 and 12 are cross-sectional views illustrating an example of a method for manufacturing a phase change memory device according to further another embodiment.

### DETAILED DESCRIPTION

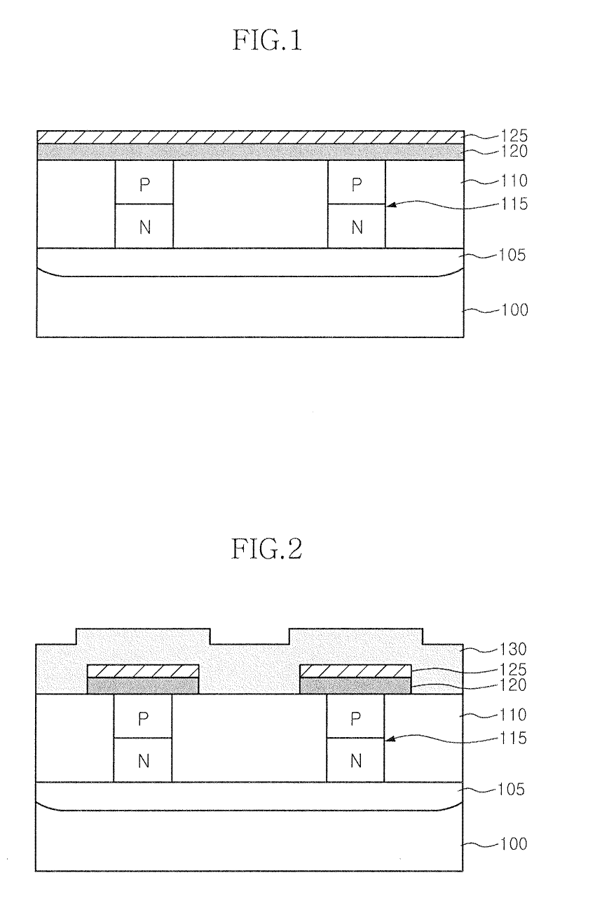

It is understood herein that the drawings are not necessarily to scale and in some instances proportions may have been exaggerated in order to more clearly depict certain features of the invention. Also it is understood that the present invention is not limited to these particular exemplary embodiments disclosed below and that the present invention can be implemented in any number of various alternate forms which are too numerous to be discussed in detail. These present exemplary embodiments are provided for illustrative purposes to allow one skilled in the art to more easily grasp the essence of the present invention FIGS. 1 to 4 are cross-sectional views illustrating an example of a method for manufacturing a phase change memory device according to one embodiment.

Referring to FIGS. 1 to 4, a word line region 105 is formed by implanting n-type impurities into a predetermined portion of a semiconductor substrate 100 in a form of general MOS transistor junctions. A first interlayer insulating layer 110 is formed on the resulting structure of the semiconductor substrate 100 in which the word line region 105 is formed. Thereafter, a portion of the first interlayer insulating layer 110 is selectively etched away to expose a portion of the word line region 105, thereby forming a contact hole (not shown). A PN diode 115 is then formed within the contact hole by using a selective epitaxial growth process and a subsequent ion-implantation process.

An ohmic contact layer 120 and a bottom electrode contact layer 122 are sequentially formed on the first interlayer insulating layer 110 and on the PN diode 115. At this time, since the thickness of the bottom electrode contact layer 122 determines a contact area between the bottom electrode contact layer 122 and a phase change layer to be formed, the bottom electrode contact layer 122 has to be formed in consideration of the contact area and current transmission. Further, since the thickness of the deposition can be adjusted at a few (0.1 Å to 100 Å) Angstroms in the current fabrication process of the semiconductor device, then the thickness of the bottom electrode contact layer 122 can be adjusted appropriately in consideration of the contact area. The ohmic contact layer 120 can include, but not limited to, a cobalt silicide (CoSi₂) layer. Various other silicide layers can be used as the ohmic contact layer 120. Also, a high resistance material, such as a titanium nitride layer, a titanium aluminum nitride layer, a doped polysilicon layer, or a doped silicon germanium layer, can be used as the bottom electrode contact layer 122.

Referring to FIG. 2, the bottom electrode contact layer 122 and the ohmic contact layer 120 are selectively patterned to be disposed on the PN diode 115. The reference numeral 125 corresponds to a remaining portion of the bottom electrode contact pattern layer and denotes the patterned portion of the bottom electrode contact layer 122 disposed on the PN diode 115. Here, each of the bottom electrode contact pattern layer 125 and the ohmic contact layer 120 preferably has a wider diameter (width) than the PN diode 115. Accordingly, it is possible to guarantee a sufficient contact area between the PN diode 115 and the bottom electrode contact pattern layer 125 and to improve the subsequent current delivering characteristics of the PRAM. Next, a phase change layer 130 is deposited on the resulting structure of the semiconductor substrate 100.

Referring to FIG. 3, phase change pattern layers 135a and 135b are formed on the sidewalls of the bottom electrode contact pattern layer 125 by selectively etching and patterning the phase change layer 130. In one embodiment, the phase change pattern layers 135a and 135b are formed and contact the sidewalls of the bottom electrode contact pattern layer 125 in such a manner that the bottom electrode contact pattern layer 125. Furthermore, since the contact area between the phase change pattern layers 135a and 135b and the bottom electrode contact pattern layer 125 can be adjusted by the thickness of the bottom electrode contact pattern layer 125, then a small contact area can be obtained. At this time, the phase change pattern layers 135a and 135b can be patterned separately on opposing sidewalls of the bottom electrode contact pattern layer 125 or patterned in a hollow cylindrical shape on the sidewall of the bottom electrode contact pattern layer 125.

Thereafter, a second interlayer insulating layer 140 is deposited on the resulting structure, in which the phase change pattern layers 135a and 135b are formed on the semiconductor substrate 100, and a planarization process i.e., CMP (chemical mechanical polishing) is subsequently applied to both the second interlayer insulating layer 140 and the phase change pattern layers 135a and 135b.

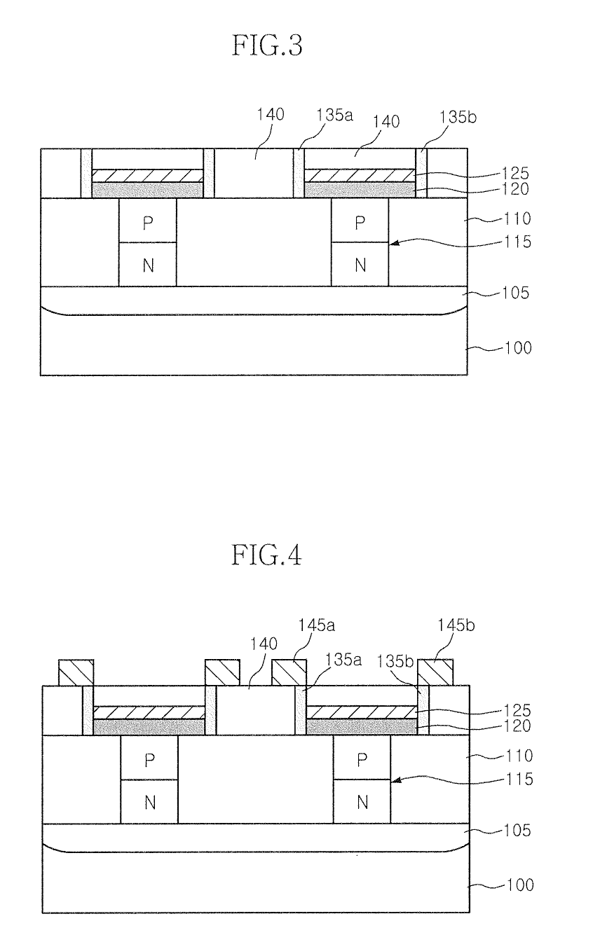

Referring to FIG. 4, upper electrodes 145a and 145b are formed on both the phase change pattern layers 135a and 135b and the second interlayer insulating layer 140, being in connect with the phase change pattern layers 135a and 135b, in pillar-type formation. The upper electrodes 145a and 145b can be formed separately on the phase change pattern layers 135a and 135b, or in a single cylindrical type formation as shown in FIG. 4. The upper electrodes 145a and 145b can also be formed in a single plate type (i.e., single-plate-type upper electrode 145) on the phase change pattern layers 135a and 135b, as shown in FIG. 5.

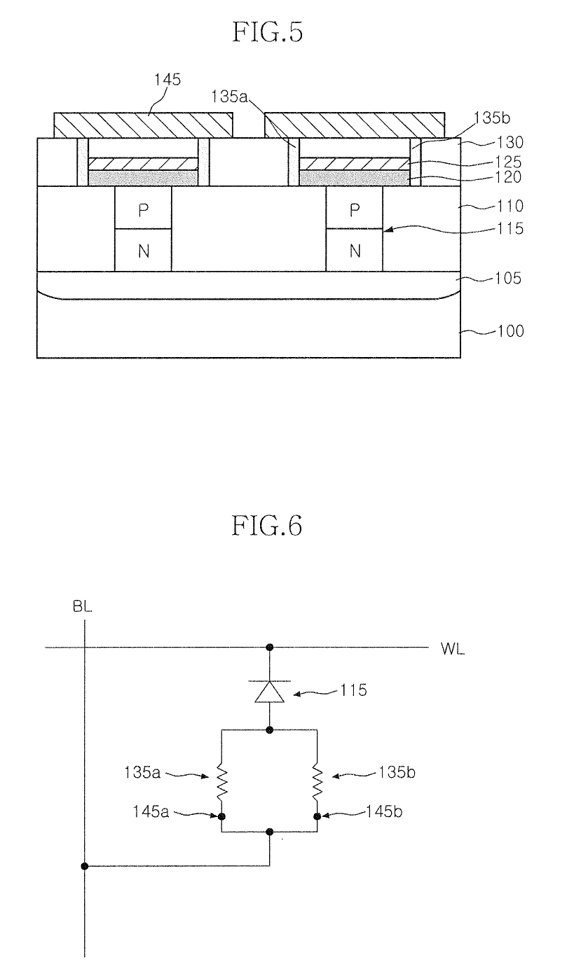

Here, in the case where a pair of the phase change pattern layers 135a and 135b is formed for the one PN diode 115, an equivalent circuit can be represented as shown in FIG. 6. In the equivalent circuit, the phase change pattern layers 135a and 135b, which are connected to the PN diode 115, are connected to each other in parallel. Accordingly, a multi-bit can be realized in one memory cell, by providing a plurality of the phase change pattern layers 135a and 135b, i.e., a plurality of resistances.

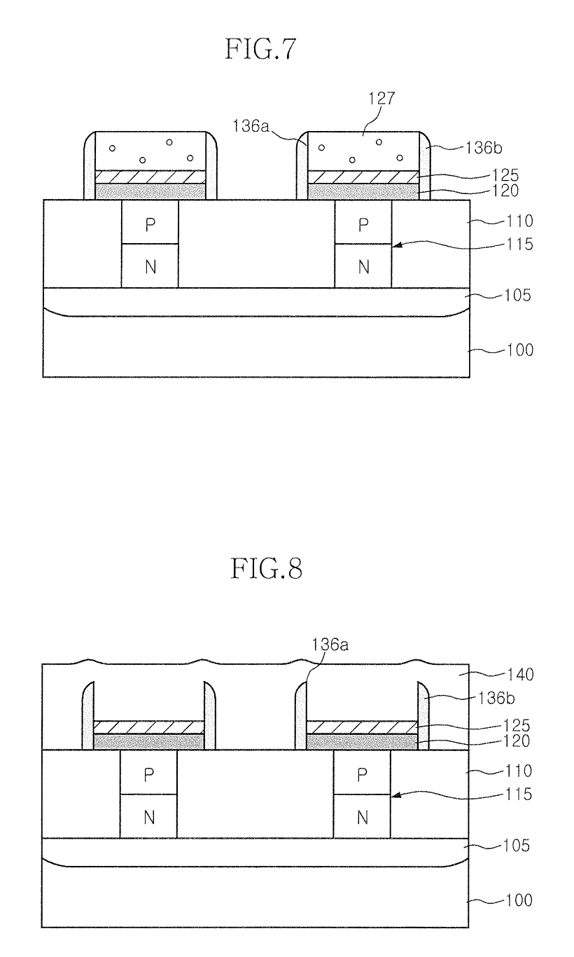

FIGS. 7 to 9 are cross-sectional views illustrating an example of a method for manufacturing a phase change memory device according to another embodiment. Elements designated with the same reference numerals in FIGS. 7 to 9 are similar to the elements designated with those reference numerals in FIGS. 1 to 5 and, therefore, are not described in detail here. In this embodiment, the formation of the bottom electrode contact layer 122 and the ohmic contact layer 120 use essentially the same processes as that in the above-mentioned embodiment. Therefore, the following processes will be described in detail.

Referring to FIG. 7, a sacrificial oxide layer is formed on the bottom electrode contact layer 122 (not shown in FIG. 7) to a predetermined thickness. The sacrificial oxide layer is used as a layer which can define a height (thickness) of the phase change layer to be formed. Therefore, the thickness of the sacrificial oxide layer has to be determined in consideration of the height of phase change patterns. First, a sacrificial oxide pattern layer 127 and the bottom electrode contact pattern layer 125 are formed by patterning the sacrificial oxide layer 127, the bottom electrode contact layer 122 and the ohmic contact layer 120 in such a manner that these pattern layers are disposed on the PN diode 115. Thereafter, a phase change layer having a predetermined thickness is deposited on the resulting structure of the semiconductor substrate 100. The thickness of the phase change layer in this embodiment can be thinner than that in the above-mentioned embodiment. Spacer layers, phase change pattern layers 136a and 136b, are formed on the sidewalls of the sacrificial oxide pattern layer 127, the bottom electrode contact pattern layer 125 and the ohmic contact layer 120 by using anisotropically etching the phase change layer.

Referring to FIG. 8, after selectively removing the sacrificial oxide pattern layer 127, the second interlayer insulating layer 140 is formed on the resulting structure of the semiconductor substrate 100 in such a manner that a space between the phase change pattern layers 136a and 136b is sufficiently buried by the second interlayer insulating layer 140.

Referring to FIG. 9, a chemical mechanical polishing process is applied to the second interlayer insulating layer 140 and the phase change pattern layers 136a and 136b and then the surface of the resulting structure of the semiconductor substrate 100 is planarized. The reference numeral 140′ denotes the remaining planarized portion of the second interlayer insulating layer 140 and the reference numeral 136′ denotes the remaining planarized portions of the phase change pattern layers 136a and 136b. The upper electrodes 145a and 145b, which are in contact with the planarized phase change pattern layers 136′, are formed on the resulting structure of the planarized semiconductor substrate 100.

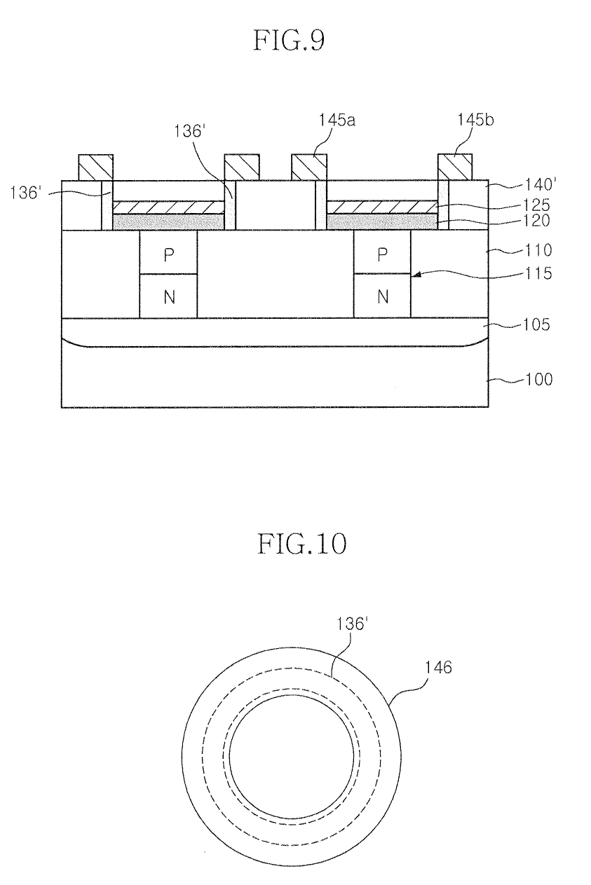

As shown in FIG. 10, the planarized phase change pattern layer 136′ can be formed in a single hollow cylindrical type design around the circumference of the bottom electrode contact pattern layer 125 (not shown in FIG. 10). The reference numeral 146 denotes a upper electrode having a single cylindrical type, which are in contact with the planarized phase change pattern layer 136′, with a wider diameter than the planarized phase change pattern layer 136′.

Similar to one embodiment, the sidewalls of the bottom electrode contact pattern layer 125 are in contact with the sidewalls of the planarized phase change pattern layers 136′ in another embodiment. As a result, the contact area between the planarized phase change pattern layers 136′ and the bottom electrode contact pattern layer 125 can be reduced effectively by adjusting only the thickness of the bottom electrode contact pattern layer 125.

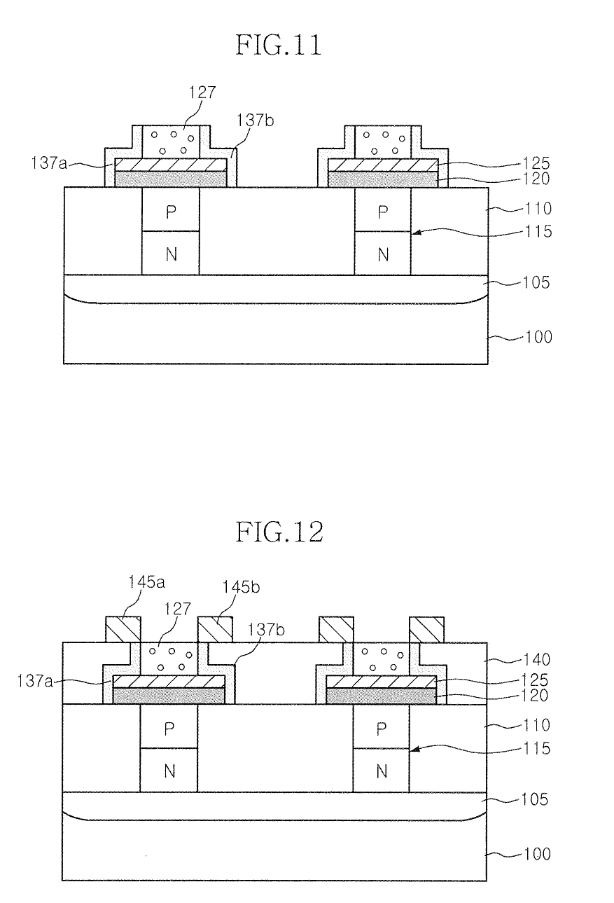

FIGS. 11 and 12 are cross-sectional views illustrating an example of a method for manufacturing a phase change memory device according to yet another embodiment. Likewise, elements designated with the same reference numerals in FIGS. 11 and 12 are similar to the elements designated with those reference numerals in FIGS. 1 to 5 and, therefore, are not described in detail here. In this embodiment, phase change pattern layers 137a and 137b are provided in a stair type.

To provide these stair-type phase change pattern layers 137a and 137b, as shown in FIG. 11, the sacrificial pattern layer 127, which has a narrower width than the bottom electrode contact pattern layer 125, is formed on the bottom electrode contact pattern layer 125 that has the ohmic contact layer 120 formed on the PN diode 115. Accordingly, a topology is created between the bottom electrode contact pattern layer 125 and the sacrificial pattern layer 127 at the sidewalls of the bottom electrode contact pattern layer 125 and the sacrificial pattern layer 127. After a phase change layer is deposited on the exposed surface of the ohmic contact layer 120, the bottom electrode contact pattern layer 125 and the sacrificial pattern layer 127, the stair-type phase change pattern layers 137a and 137b are formed by anisotropically etching the phase change layer. The anisotropic etching process is a method in which a material is selectively etched in a horizontal or vertical direction. In this embodiment, the phase change pattern layers 137a and 137b are formed by selectively removing the phase change layer which exists on a plane parallel to the semiconductor substrate 100. At the time of anisotropically etching the phase change layer, the phase change layer disposed on the bottom electrode contact pattern layer 125 is not removed because a portion of the bottom electrode contact pattern layer 125, which is exposed from the sacrificial pattern layer 127 disposed thereon, is relatively very narrow and an etchant is not provided sufficiently to the bottom electrode contact pattern layer 125 due to such the sacrificial pattern layer 127. Therefore, a portion of the phase change pattern layers 137a and 137b still remains in contact with the bottom electrode contact pattern layer 125 along a horizontal direction. Furthermore, top planes of the phase change pattern layers 137a and 137b are flat in FIG. 11. Alternately, the top planes of the phase change pattern layers 137a and 137b can be also be pointed at the end.

Next, as shown in FIG. 12, the second interlayer 140 is deposited in such a manner that the second interlayer 140 is sufficiently buried between the phase change pattern layers 137a and 137b. Thereafter, a planarization process, a chemical mechanical polishing process, is applied to the second interlayer 140 in order to form the second interlayer 140 having the matching topology as the phase change pattern layers 137a and 137b. The upper electrodes 145a and 145b, which are in contact with the phase change pattern layers 137a and 137b, are then formed on the second interlayer 140. At that time, the upper electrode can be formed in either the single cylindrical type or the single plate type configuration.

As apparent from the above, the contact area between the phase change pattern layer and the bottom electrode contact layer can be adjusted based on the thickness of the bottom electrode contact layer, by forming the phase change layer which is in contact with the sidewalls of the bottom electrode contact layer. Therefore, the contact area between the phase change pattern layer and the bottom electrode contact layer can be minimized by forming the thin-film bottom electrode contact layer.

Since the bottom electrode contact layer has a width wider than that of the switching element (PN diode), a sufficient contact area is obtained which exhibits improved electrical characteristics.

In this disclosure, while the ohmic contact layer and the bottom electrode contact layer are deposited and patterned simultaneously, they can be formed on the PN diode by using a selective silicide technique.

While certain embodiments have been described above, it will be understood that the embodiments described are by way of example only. Accordingly, the systems and methods described herein should not be limited based on the described embodiments. Rather, the systems and methods described herein should only be limited in light of the claims that follow when taken in conjunction with the above description and accompanying drawings.

What is claimed is:

1. A phase change random access memory device comprising:
a bottom electrode contact pattern layer; and
phase change pattern layer formed on a sidewall of the bottom electrode contact pattern layer such a resulting contact area between the bottom electrode contact pattern layer and the phase change pattern layers is based on a thickness of the bottom electrode contact pattern layer.

2. The phase change random access memory device of claim 1, further comprising a switching element electrically coupled to a bottom surface of the bottom electrode contact pattern layer.

3. The phase change random access memory device of claim 2, wherein the switching element is a PN diode.

4. The phase change random access memory device of claim 3, wherein the bottom electrode contact pattern layer is wider than the PN diode.

5. The phase change random access memory device of claim 4, further comprising an ohmic contact layer between the bottom electrode contact pattern layer and the PN diode.

6. The phase change random access memory device of claim 1, further comprising an upper electrode electrically coupled to an upper surface of the phase change pattern layer.

7. The phase change random access memory device of claim 6, further comprising an interlayer insulating layer formed on the phase change pattern layer such that the interlayer insulating layer has a topology matching that of the phase change pattern layer.

8. The phase change random access memory device of claim 1, wherein the phase change pattern layer has a pillar-type shape.

9. The phase change random access memory device of claim 1, wherein the phase change pattern layer have a hollow cylindrical-type shape which is disposed around a circumference of the bottom electrode contact pattern layer.

10. The phase change random access memory device of claim 1, wherein the phase change pattern layer is substantially vertical to an upper surface of the bottom electrode contact pattern layer.

11. The phase change random access memory device of claim 1, wherein the phase change pattern layer has a stair-type shape.

12. A method for forming a phase change random access memory device, the method comprising:
providing a semiconductor substrate having a switching element;
forming a bottom electrode contact pattern layer on the semiconductor substrate such that the bottom electrode contact pattern layer is electrically coupled to the switching element; and
forming a phase change pattern layer in contact with a sidewall of the bottom electrode contact pattern layer such that a resultant contact areas between the bottom electrode contact pattern layer and the phase change pattern layer is based on a thickness of the bottom electrode contact pattern layer.

13. The method of claim 12, wherein the forming of the phase change pattern layers comprises:
depositing a phase change layer on the first resulting structure; and
etching selectively the phase change layer to form the phase change pattern layer positioned on a sidewalls of the bottom electrode contact pattern layer.

14. The method of claim 12, wherein the forming of the phase change pattern layer includes:
forming a sacrificial pattern layer on the bottom electrode contact pattern layer;
depositing a phase change layer on the bottom electrode contact pattern layer and on the sacrificial pattern layer;
anisotropically etching the phase change layer; and
removing the sacrificial pattern layer.

15. The method of claim 14, wherein the sacrificial pattern layer is substantially the same width as that of the bottom electrode contact pattern layer.

16. The method of claim 14, wherein the sacrificial pattern layer is narrower in width as that the bottom electrode contact pattern layer.

17. The method of claim 12, after the forming of the phase change pattern layers, further comprising:
depositing an interlayer insulating layer on the second resulting structure;
applying a planarization process to the interlayer insulating layer such that the interlayer insulating layer substantially matches the topology as that of the phase change pattern layer; and
forming an upper electrode on the phase change pattern layer such that the upper electrode is electrically coupled to the phase change pattern layer.

18. A phase change random access memory device comprising:
a PN diode formed on a semiconductor substrate;
a bottom electrode contact pattern layer electrically coupled to the PN diode such that the bottom electrode contact pattern layer is wider than the PN diode;
a phase change pattern layer formed on a sidewall of the bottom electrode contact pattern layer;
an interlayer insulating layer on the phase change pattern layer; and
an upper electrode on the phase change pattern layers such that the upper electrode is electrically coupled to the phase change pattern layers,
wherein where the bottom electrode contact pattern layer contacts the phase change pattern layers is based on a thickness of the bottom electrode contact pattern layer.

19. The phase change random access memory device of claim 18, wherein the bottom electrode contact pattern layer is wider than the PN diode.

20. The phase change random access memory device of claim 18, further comprising an ohmic contact layer between the bottom electrode contact pattern layer and the PN diode.

21. The phase change random access memory device of claim 18, further comprising an interlayer insulating layer formed on the phase change pattern layers such that the interlayer insulating layer has substantially the same topology as that of the phase change pattern layers.

22. The phase change random access memory device of claim 18, wherein the phase change pattern layer has a pillar-type shape and the phase change pattern layer is taller than the width of the bottom electrode contact pattern layer.

23. The phase change random access memory device of claim 22, wherein the upper electrode contacts the phase change pattern layer.

24. The phase change random access memory device of claim 18, wherein the phase change pattern layer has a hollow cylindrical-type shape around a circumference of the bottom electrode contact pattern layer and the height of the phase change pattern layers is greater than width of the bottom electrode contact pattern layer.

25. The phase change random access memory device of claim 24, wherein the upper electrode is in contact with the phase change pattern layer.

26. The phase change random access memory device of claim 18, wherein the phase change pattern layer is substantially vertical relative to an upper surface of the bottom electrode contact pattern layer.

27. The phase change random access memory device of claim 18, wherein the phase change pattern layers has a stair-type shape.

28. A method for forming a phase change random access memory device, the method comprising:
providing a semiconductor substrate having a switching element;
forming a bottom electrode contact pattern layer on the semiconductor substrate such that the bottom electrode contact pattern layer is electrically coupled to the switching element;
forming a phase change pattern layer in contact with a sidewall of the bottom electrode contact pattern layer;
burying and planarizing an interlayer insulating layer on the phase change pattern layer; and
forming an upper electrode on the phase change pattern layer to electrically couple together the upper electrode to the phase change pattern layer,
wherein where the bottom electrode contact pattern layer contacts the phase change pattern layer is based on a thickness of the bottom electrode contact pattern layer.

29. The method of claim 28, wherein the forming of the phase change pattern layers includes:
depositing a phase change layer on the first resulting structure; and
patterning the phase change layer to position the phase change layer pattern on the sidewall of the bottom electrode contact pattern layer.

30. The method of claim 28, wherein the forming of the phase change pattern layers includes:
forming a sacrificial pattern layer on the bottom electrode contact pattern layer;
depositing a phase change layer on the bottom electrode contact pattern layer and the sacrificial pattern layer;
anisotropically etching the phase change layer; and
removing the sacrificial pattern layer.

31. The method of claim 28, wherein the sacrificial pattern layer substantially the same width as that of the bottom electrode contact pattern layer.

32. The method of claim 28, wherein the sacrificial pattern layer is thinner than the bottom electrode contact pattern layer.

33. The method of claim 28, wherein the burying of the interlayer insulating layer includes:
depositing the interlayer insulating layer; and
removing a portion of the interlayer insulating layer and a portion of the phase change pattern layer using a chemical mechanical polishing process such that the interlayer insulating layer has substantially the same topology as that of the phase change pattern layer.
